(19) United States
(12) Patent Application Publication
(10) Pub. No.: US 2009/0288862 A1
(43) Pub. Date: Nov. 26, 2009

(54) Wired circuit board and producing method thereof

(75) Inventors: Yasushi Tamura, Osaka (JP); Hayato Abe, Osaka (JP); Katsuhiko Kawashima, Osaka (JP)

Correspondence Address: AKERMAN SENTERFITT, 8100 BOONE BOULEVARD, SUITE 700, VIENNA, VA, 22182-2683, US

(73) Assignee: Nitto Denko Corporation, Osaka (JP)

(21) Appl. No.: 12/453,542

(22) Filed: May 14, 2009

Related U.S. Application Data
(60) Provisional application No. 61/129,058, filed on Jun. 2, 2008.

(30) Foreign Application Priority Data
May 20, 2008 (JP) 2008-132431

(51) Int. Cl. H05K 1/09; B05D 5/12; B32B 38/00

(52) U.S. Cl. 174/257; 427/97.4; 156/60

(57) ABSTRACT

A wired circuit board includes an insulating base layer, a conductive pattern formed on the insulating base layer, a tin-based thin layer formed on a surface of the conductive pattern, and containing at least tin oxide, and an insulating cover layer formed on the insulating base layer so as to cover the tin-based thin layer.

### CROSS-REFERENCE TO RELATED APPLICATION

This application claims the benefit of U.S. Provisional Application No. 61/129,058, filed on Jun. 2, 2008, and claims priority from Japanese Patent Application No. 2008-132431, filed on May 20, 2008, the contents of which are herein incorporated by reference in their entirety.

### BACKGROUND OF THE INVENTION

1. Field of the Invention

The present invention relates to a wired circuit board and to a producing method thereof.

2. Description of the Related Art

A wired circuit board includes an insulating base layer, a conductive pattern formed on the insulating base layer, and an insulating cover layer formed on the insulating base layer so as to cover the conductive pattern. It has been known that, in such a wired circuit board, a tin layer is provided on the surface of the conductive pattern.

For example, it has been proposed to obtain a film carrier tape for mounting an electronic component by forming a tin plating layer on the entire surface of a wiring pattern made of copper and lying on a polyimide film, coating a solder resist thereon, exposing the solder resist to light, developing it, and curing it by performing heating at 150° C. for 60 minutes (see, e.g., Japanese Unexamined Patent Nos. 2001-144145 and 2000-36521).

In the film carrier tape for mounting an electronic component proposed in Japanese Unexamined Patent Nos. 2001-144145 and 2000-36521, a copper-diffused tin plating layer is formed by diffusing copper in the wiring pattern into the tin plating layer.

### SUMMARY OF THE INVENTION

However, in the film carrier tape for mounting an electronic component proposed in Japanese Unexamined Patent Nos. 2001-144145 and 2000-36521, the adhesion between the wiring pattern covered with the copper-diffused tin plating layer and the solder resist is insufficient. Accordingly, there is a problem that, as a result of long-term use of the film carrier tape for mounting an electronic component, the solder resist floats up from the wiring pattern, and the wiring pattern is corroded.

It is therefore an object of the present invention to provide a wired circuit board and a producing method thereof which can prevent the degradation of the adhesion between a conductive pattern covered with a tin alloy layer and an insulating cover layer.

To attain the object, a wired circuit board of the present invention includes an insulating base layer, a conductive pattern formed on the insulating base layer, a tin-based thin layer formed on a surface of the conductive pattern, and containing at least tin oxide, and an insulating cover layer formed on the insulating base layer so as to cover the tin-based thin layer.

In the wired circuit board of the present invention, it is preferable that the tin-based thin layer includes a tin oxide layer made of the tin oxide, and a thickness of the tin oxide layer is in a range of 5 to 50 nm.

The wired circuit board of the present invention is obtained by a producing method of a wired circuit board, the producing method including forming an insulating base layer, forming a conductive pattern on the insulating base layer, forming a tin layer on a surface of the conductive pattern, heating the tin layer in vacuum to a temperature of not less than 350° C., cooling, after the heating, the tin layer under an atmospheric pressure to form a tin-based thin layer containing at least tin oxide, and forming an insulating cover layer on the insulating base layer so as to cover the tin-based thin layer.

Alternatively, the wired circuit board of the present invention is obtained by a producing method of a wired circuit board, the producing method including forming an insulating base layer, forming a conductive pattern on the insulating base layer, forming a tin layer on a surface of the conductive pattern, heating the tin layer in vacuum to a temperature of not less than 350° C., cooling, after the heating, the tin layer in vacuum, heating, after the cooling, the tin layer to a temperature of not less than 150° C. under an atmospheric pressure to form a tin-based thin layer containing at least tin oxide, and forming an insulating cover layer on the insulating base layer so as to cover the tin-based thin layer.

In the wired circuit board of the present invention, it is preferable that the step of forming the insulating cover layer includes laminating an uncured resin, and curing the laminated uncured resin by heating, and the curing and the heating are simultaneously performed.

A producing method of a wired circuit board of the present invention includes forming an insulating base layer, forming a conductive pattern on the insulating base layer, forming a tin layer on a surface of the conductive pattern, heating the tin layer in vacuum to a temperature of not less than 350° C., cooling, after the heating, the tin layer under an atmospheric pressure to form a tin-based thin layer containing at least tin oxide, and forming an insulating cover layer on the insulating base layer so as to cover the tin-based thin layer.

Alternatively, the producing method of a wired circuit board of the present invention includes forming an insulating base layer, forming a conductive pattern on the insulating base layer, forming a tin layer on a surface of the conductive pattern, heating the tin layer in vacuum to a temperature of not less than 350° C., cooling, after the heating, the tin layer in vacuum, heating, after the cooling, the tin layer to a temperature of not less than 150° C. under an atmospheric pressure to form a tin-based thin layer containing at least tin oxide, and forming an insulating cover layer on the insulating base layer so as to cover the tin-based thin layer.

In the producing method of a wired circuit board of the present invention, it is preferable that the step of forming the insulating cover layer includes laminating an uncured resin, and curing the laminated uncured resin by heating, and the curing and the heating are simultaneously performed.

In the wired circuit board and the producing method thereof of the present invention, the tin-based thin layer containing at least the tin oxide is interposed between the conductive pattern and the insulating cover layer. Therefore, it is possible to prevent the degradation of the adhesion between the conductive pattern and the insulating cover layer.

As a result, even after the long-term use of the wired circuit board, it is possible to prevent the insulating cover layer from peeling from the conductive pattern, and prevent the occurrence of discoloration of the conductive pattern.

### BRIEF DESCRIPTION OF THE DRAWINGS

FIG. 1 is a plan view showing a principal portion of a suspension board with circuit as an embodiment of a wired circuit board of the present invention;

FIG. 2 is a cross-sectional view of the principal portion of the suspension board with circuit shown in FIG. 1 along a longitudinal direction thereof;

FIG. 3 is an enlarged cross-sectional view of a tin-based thin layer shown in FIG. 2;

FIG. 4 is a production process view showing a producing method of the suspension board with circuit shown in FIG. 2 as an embodiment of a producing method of a wired circuit board of the present invention,

(a) showing the step of preparing a metal supporting board,

(b) showing the step of forming an insulating base layer on the metal supporting board,

(c) showing the step of forming a conductive pattern on the insulating base layer,

(d) showing the step of forming a tin layer on the surface of the conductive pattern, and

(e) showing the step of forming a cover coating;

FIG. 5 is a production process view showing, subsequently to FIG. 4, the producing method of the suspension board with circuit shown in FIG. 2 as the embodiment of the producing method of a wired circuit board of the present invention,

(f) showing the step of curing the cover coating by heating, while forming a tin-based thin layer,

(g) showing the step of forming a metal opening in the metal supporting board,

(h) showing the step of forming a base opening in the insulating base layer, and

(i) showing the step of forming a metal plating layer;

FIG. 6 is an enlarged cross-sectional view of the tin-based thin layer in the suspension board with circuit as another embodiment (in which the tin layer remains) of the wired circuit board of the present invention; and

FIG. 7 is a graph showing the relationship between the thickness of the tin-based thin layer and a peel strength in each of EXAMPLES.

### DETAILED DESCRIPTION OF THE INVENTION

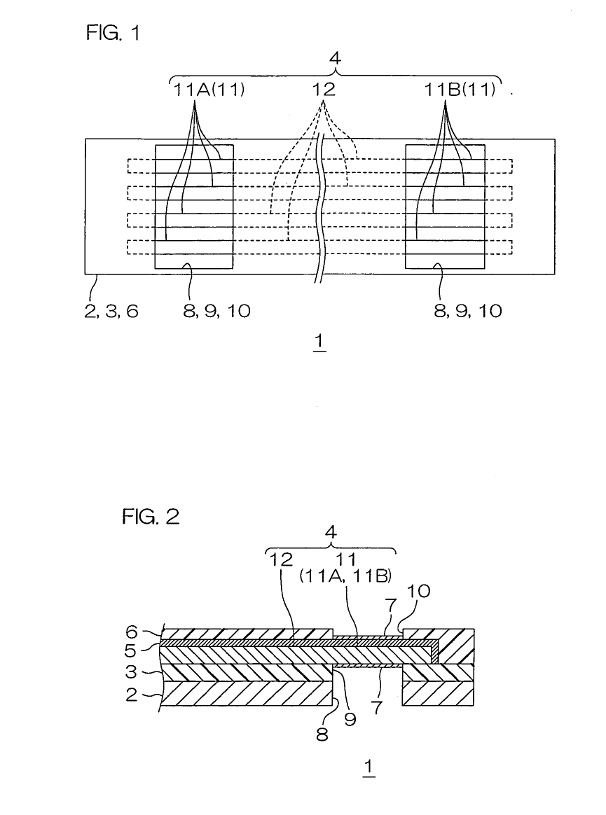

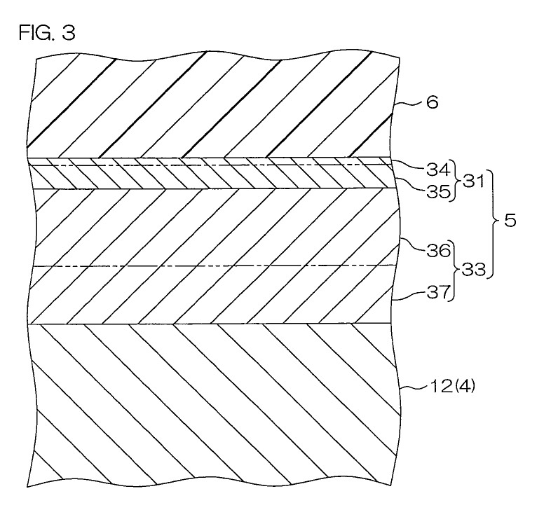

FIG. 1 is a plan view showing a principal portion of a suspension board with circuit as an embodiment of a wired circuit board of the present invention. FIG. 2 is a cross-sectional view of the principal portion of the suspension board with circuit shown in FIG. 1 along a longitudinal direction thereof (which may be hereinafter simply referred to as the “longitudinal direction”). FIG. 3 is an enlarged cross-sectional view of a tin-based thin layer (described later) shown in FIG. 2. In FIG. 1, the tin-based thin layer and a metal plating layer, each described later, are omitted for clear illustration of relative positioning of a conductive pattern.

A suspension board with circuit 1 is attached to a hard disk drive to mount a magnetic head not shown, and support the magnetic head in opposing relation to a magnetic disk. The suspension board with circuit 1 is formed with a conductive pattern 4 for connecting the magnetic head and an external circuit such as a read/write board not shown.

As shown in FIG. 2, the suspension board with circuit 1 includes a metal supporting board 2, an insulating base layer 3 formed on the metal supporting board 2, a conductive pattern 4 formed on the insulating base layer 3, and an insulating cover layer 6 formed on the insulating base layer 3 so as to cover the conductive pattern 4.

As shown in FIG. 1, the metal supporting board 2 is in a rectangular thin-plate plan view shape extending in the longitudinal direction, and formed of a metal foil or a metal thin plate. Examples of a metal material used to form the metal supporting board 2 include stainless steel and a 42-alloy. Preferably, stainless steel is used. The thickness of the metal supporting board 2 is in a range of, e.g., 10 to 60 μm, or preferably 15 to 30 μm.

The insulating base layer 3 is laminated on the upper surface of the metal supporting board 2. More specifically, the insulating base layer 3 is formed in a pattern corresponding to the surface portion of the metal supporting board 2 where wires 12 of the conductive pattern 4 are formed.

Examples of an insulating material used to form the insulating base layer 3 include synthetic resins such as polyimide, polyether nitrile, polyether sulfone, polyethylene terephthalate, polyethylene naphthalate, and polyvinyl chloride. Among these, a photosensitive synthetic resin is preferably used, or more preferably, photosensitive polyimide is used. The thickness of the insulating base layer 3 is in a range of, e.g., 1 to 30 μm, or preferably 2 to 20 μm.

The conductive pattern 4 integrally and continuously includes magnetic-head-side connection terminal portions 11A, external connection terminal portions 11B, and the wires 12 for connecting the magnetic-head-side connection terminal portions 11A and the external connection terminal portions 11B.

The plurality of (four) wires 12 are provided along the longitudinal direction, and arranged in parallel to be spaced apart from each other in a widthwise direction (perpendicular to the longitudinal direction).

The magnetic-head-side connection terminal portions 11A are disposed on the front end portion (longitudinal one end portion) of the metal supporting board 2, and arranged in parallel to be spaced apart from each other along the widthwise direction. The plurality of (four) magnetic-head-side connection terminal portions 11A are provided so as to be connected to the respective front end portions of the wires 12.

As shown in FIG. 2 and described later, the magnetic-head-side connection terminal portions 11A are provided such that the lower surfaces thereof are exposed from the metal supporting board 2 and the insulating base layer 3, and the upper surfaces thereof are exposed from the insulating cover layer 6. The magnetic-head-side connection terminal portions 11A are connected to terminal portions (not shown) of the magnetic head.

As shown in FIG. 1, the external connection terminal portions 11B are disposed on the rear end portion (the longitudinal other end portion) of the metal supporting board 2, and arranged in parallel to be spaced apart from each other along the widthwise direction. The plurality of (four) external connection terminal portions 11B are provided so as to be connected to the respective rear end portions of the wires 12.

As shown in FIG. 2 and described later, the external connection terminal portions 11B are provided such that the lower surfaces thereof are exposed from the metal supporting board 2 and the insulating base layer 3, and the upper surfaces thereof are exposed from the insulating cover layer 6. The external connection terminal portions 11B are connected to terminal portions (not shown) of the read/write board.

Examples of a conductive material used to form the conductive pattern 4 include copper, nickel, gold, a solder, or an alloy thereof. Preferably, copper is used.

The thickness of the conductive pattern 4 is in a range of, e.g., 1 to 15 μm, or preferably 3 to 12 μm. The respective widths of the wires 12, the magnetic-head-side connection terminal portions 11A, and the external connection terminal portions 11B are, e.g., the same as or different from each other, and in a range of, e.g., 50 to 500 μm, or preferably 80 to 300 μm. The respective spacings between the wires 12, between the magnetic-head-side connection terminal portions 11A, and between the external connection terminal portions 11B are the same as or different from each other, and in a range of, e.g., 5 to 500 μm, or preferably 15 to 100 μm.

The magnetic-head-side connection terminal portions 11A and the external connection terminal portions 11B are hereinafter simply described as terminal portions 11 when distinction therebetween is not particularly needed.

The insulating cover layer 6 is formed to cover the conductive pattern 4, and cover the upper surface of the insulating base layer 3 exposed from the conductive pattern 4. More specifically, as shown in FIG. 2, the insulating cover layer 6 is formed in the same pattern as that of the insulating base layer 3 when viewed in plan view. The thickness of the insulating cover layer 6 is in a range of, e.g., 1 to 20 μm, or preferably 2 to 10 μm.

In the suspension board with circuit 1, respective openings are formed in the respective portions of the metal supporting board 2, the insulating base layer 3, and the insulating cover layer 6 which correspond to the terminal portions 11.

More specifically, in the portion of the metal supporting board 2 where the terminal portions 11 are formed, a metal opening 8 is formed to extend therethrough in the thickness direction. As shown in FIG. 1, the metal opening 8 is formed in a generally rectangular plan view shape so as to include all the (four) terminal portions 11 when viewed in plan view.

In the portion of the insulating base layer 3 where the terminal portions 11 are formed, a base opening 9 is formed to extend therethrough in the thickness direction. The base opening 9 is formed in the same shape as that of the metal opening 8 so as to include all the (four) terminal portions 11 when viewed in plan view. That is, when viewed in plan view, the base opening 9 is formed such that the both longitudinal end edges and both widthwise end edges thereof are at the same positions as those of the both longitudinal end edges and both widthwise end edges of the metal opening 8.

As a result, the lower surfaces of the terminal portions 11 are exposed from the metal opening 8 of the metal supporting board 2 and from the base opening 9 of the insulating base layer 3.

In the portion of the insulating cover layer 6 where the terminal portions 11 are formed, a cover opening 10 is formed to extend therethrough in the thickness direction. The cover opening 10 is formed in the same shape as that of the base opening 9 so as to include all the (four) terminal portions 11 when viewed in plan view. That is, when viewed in plan view, the cover opening 10 is formed such that the both longitudinal end edges and both widthwise end edges thereof are at the same positions as those of the both longitudinal end edges and both widthwise end edges of the base opening 9.

As a result, the upper surfaces and both side surfaces of the terminal portions 11 are exposed from the cover opening 10 of the insulating cover layer 6.

In other words, the terminal portions 11 are formed as flying leads such that the respective surfaces (the upper surfaces, both side surfaces, and lower surfaces) thereof are exposed from the metal opening 8, the base opening 9, and the cover opening 10.

In the suspension board with circuit 1, a tin-based thin layer 5 is formed on the surface of the conductive pattern 4.

As shown in FIG. 2, the tin-based thin layer 5 is covered with the insulating cover layer 6 in the portion where the wires 12 are formed to be interposed between the wires 12 and the insulating cover layer 6. In the portion where the terminals 11 are formed, the tin-based thin layer 5 is exposed from the metal opening 8, the base opening 9, and the cover opening 10.

The tin-based thin layer 5 is provided continuously over the upper surface and side surfaces (i.e., the both widthwise side surfaces and the both longitudinal side surfaces) of the conductive pattern 4 (the wires 12 and the terminal portions 11). More specifically, the tin-based thin layer 5 is formed to erode the upper surface, both widthwise side surfaces, and both longitudinal side surfaces of the conductive pattern 4.

The tin-based thin layer 5 contains at least tin oxide. Specifically, a tin-based material for forming the tin-based thin layer 5 is represented by the following composition formula:

MtₐSn_{b}O (1)

(wherein Mt represents an atom of at least one metal selected from the group consisting of copper, nickel and gold, and a and b satisfy 0<(a/b)<1).

In the composition formula (1), Mt is preferably copper.

The tin-based thin layer 5 may also be formed of layers of a plurality of different metals. In that case, as shown in FIG. 3, the tin-based thin layer 5 includes a tin alloy layer 33 made of a tin alloy, and a tin oxide layer 31 formed on the surface of the tin alloy layer 33, and made of tin oxide.

The tin alloy layer 33 covers the surfaces (the upper surface, both widthwise side surfaces, and both longitudinal side surfaces) of the conductive pattern 4 to form the innermost surface of the tin-based thin layer 5 which is in contact with the conductive pattern 4.

The tin alloy layer 33 is made of, e.g., an alloy (tin alloy) of tin and the conductive material forming the conductive pattern 4. Specifically, when the conductive pattern 4 is made of copper, the tin alloy layer 33 is formed of a tin-copper alloy of tin and copper.

The tin alloy (specifically, the tin-copper alloy) forming the tin alloy layer 33 is represented by a composition formula such as, e.g., Cu₄₁Sn₁₁, Cu₁₀Sn₃, Cu₁₁Sn₉, Cu₃Sn, Cu₆Sn₅, Cu₃₉Sn₁₁, or Cu₈₁Sn₂₂. The tin-copper alloy can also be simply represented by CuₓSn_{y} (where x and y satisfy (x/y)≧1.11) as a generic formula of the composition formulae (molecular formulae) shown above.

As the tin alloy forming the tin alloy layer 33, the tin oxides represented by the foregoing formulae can be used either alone or in a combination of two or more. Preferably, Cu₆Sn₅ and Cu₃Sn are used in combination.

Specifically, the tin alloy layer 33 includes a first tin alloy layer 37 made of Cu₃Sn, and a second tin alloy layer 36 made of Cu₆Sn₅ and formed on the surface of the first tin alloy layer 37.

In the tin alloy layer 33, the thickness of the first tin alloy layer 37 is in a range of, e.g., 1 to 1500 nm, or preferably 200 to 800 nm, and the thickness of the second tin alloy layer 36 is in a range of, e.g., 1 to 1500 nm, or preferably 200 to 800 nm.

The tin oxide layer 31 is formed on the surface of the tin alloy layer 33 to form the outermost surface of the tin-based thin layer 5 which is in contact with the insulating cover layer 6.

The tin oxide forming the tin oxide layer 31 is represented by a composition formula such as SnO (tin oxide (II)), SnO₂ (tin oxide (IV)), Sn₂O₃ (tin trioxide), Sn₃O₄, Sn₇O₁₃, or SnO₄. The tin oxide can also be simply represented by SnO_{z} (where z satisfies 0<z<5) as a generic formula of the molecular formulae shown above. The tin alloys represented by the foregoing formulae can be used either alone or in a combination of two or more. Preferably, SnO and SnO₂ are used in combination.

Specifically, the thin oxide layer 31 includes a first tin oxide layer 35 made of SnO₂, and a second tin oxide layer 34 made of SnO and formed on the surface of the first tin oxide layer 35.

The thickness of the tin oxide layer 31 is in a range of, e.g., 5 to 50 nm, or preferably 5 to 20 nm. In the tin oxide layer 31, the thickness of the first tin oxide layer 35 is in a range of, e.g., 0.1 to 50 nm, or preferably 0.1 to 10 nm, and the thickness of the second tin oxide layer 34 is in a range of, e.g., 1 to 50 nm, or preferably 3 to 30 nm.

When the thickness of the tin oxide layer 31 is under the range shown above, it may be impossible to prevent the degradation of the adhesion between the wires 12 and the insulating cover layer 6. Further, it may be impossible to improve the strength of the terminal portions 11. When the thickness of the tin-based thin layer 5 is over the range shown above, the surface resistivity at the terminal portions 11 may be excessively high.

The thickness of the tin-based thin layer 5 is the total of the thicknesses of the individual layers shown above, and in a range of, e.g., 500 to 1500 nm, or preferably 700 to 1100 nm.

The composition and thickness of the tin-based thin layer 5 (i.e., the first tin alloy layer 37, the second tin alloy layer 36, the first tin oxide layer 35, and the second tin oxide layer 34) mentioned above can be measured individually by field emission scanning electron microscopy (FE-SEM), transmission electron microscopy (TEM), energy dispersive X-ray spectrometry (EDS), Auger electron spectrometry (AES), electron probe microanalysis (EPMA), or the like. The composition and thickness of the tin-based thin layer 5 can also be measured by a SERA method (IPC-4554).

As an insulating material used to form the insulating cover layer 6, the same insulating material as used to form the insulating base layer 3 mentioned above is used. The thickness of the insulating cover layer 6 is in a range of, e.g., 2 to 10 μm, or preferably 3 to 6 μm.

In the suspension board with circuit 1, as shown in FIG. 2, a metal plating layer 7 is formed on the surface of the tin-based thin layer 5 at the terminal portions 11.

More specifically, the metal plating layer 7 is formed continuously on the lower surfaces of the terminal portions 11 and on the surface of the tin-based thin layer 5 (the second tin oxide layer 34) which is formed on the upper surfaces and both side surfaces of the terminal portions 11. Examples of a metal material used to form the metal plating layer 7 include gold and nickel. Preferably, gold is used. The thickness of the metal plating layer 7 is in a range of, e.g., 0.2 to 5 μm, or preferably 0.5 to 3 μm.

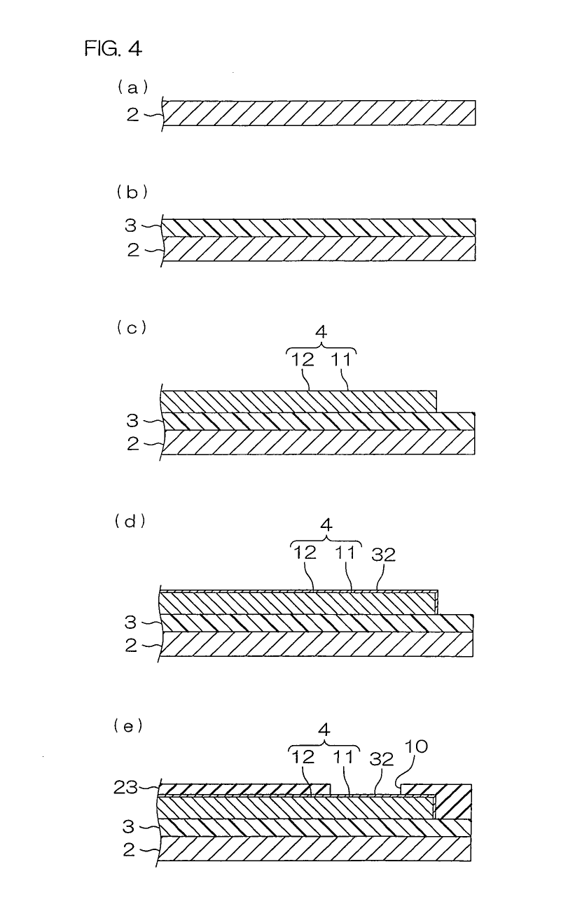

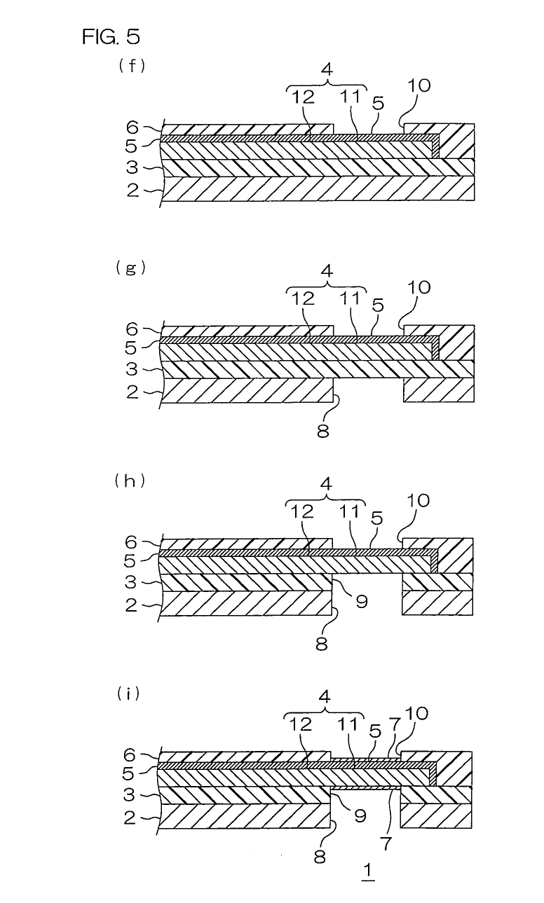

Next, a producing method of a suspension board with circuit as an embodiment of a producing method of a wired circuit board of the present invention is described with reference to FIGS. 4 and 5.

In the method, as shown in FIG. 4(a), the metal supporting board 2 is prepared first.

Next, as shown in FIG. 4(b), the insulating base layer 3 is formed on the metal supporting board 2.

To form the insulating base layer 3, e.g., a varnish (photosensitive polyamic acid resin solution) of a photosensitive polyimide resin precursor is uniformly coated first on the entire surface of the metal supporting board 2, and dried by heating at, e.g., 70 to 120° C. to form a base coating. Then, the base coating is exposed to light via a photomask, developed, and then cured (imidized) by heating at, e.g., 350 to 400° C. to form the insulating base layer 3 in the foregoing pattern on the metal supporting board 2.

Next, as shown in FIG. 4(c), the conductive pattern 4 is formed in the foregoing pattern on the insulating base layer 3.

The conductive pattern 4 is formed by a known patterning method such as, e.g., an additive method or a subtractive method. Preferably, the conductive pattern 4 is formed by the additive method.

That is, in the additive method, a seed film not shown is formed first on the entire surface of the insulating base layer 3. As a material for forming the seed film, a metal material such as, e.g., copper, chromium, or an alloy thereof is used. The seed film is formed by sputtering, electrolytic plating, electroless plating, or the like. Then, a dry film resist is provided on the surface of the seed film, exposed to light, and developed to form a plating resist not shown in a pattern reverse to the conductive pattern 4. Then, the conductive pattern 4 is formed by plating on the surface of the seed film exposed from the plating resist. Subsequently, the plating resist and the portion of the seed film where the plating resist is formed are removed by etching or the like. As the plating, electrolytic copper plating is preferably used.

Next, as shown in FIG. 4(d), a tin layer 32 is formed on the surface of the conductive pattern 4.

The tin layer 32 is formed on the surface of the conductive pattern 4 by, e.g., electroless tin plating.

In the electroless tin plating, when the conductive pattern 4 is made of copper, the surface of the conductive pattern 4 is etched through the substitution of tin for copper. More specifically, the tin layer 32 is formed so as to erode the upper surface, both widthwise side surfaces, and both longitudinal side surfaces of the conductive pattern 4.

The thickness of the tin layer 32 (tin layer 32 before a heating step) is in a range of, e.g., 1 to 2000 nm, or preferably 200 to 500 nm. When the thickness of the tin layer 32 before the heating step is not in the range shown above, it may be impossible to form the tin-based thin layer 5 having a thickness within the range shown above in a subsequent step.

Next, as shown in FIG. 4(e), a cover coating 23 is formed in the foregoing pattern.

The cover coating 23 is made of an uncured resin before the insulating cover layer 6 is formed.

In the case where the cover coating 23 is formed using, e.g., photosensitive polyimide, a solution of a photosensitive polyamic acid resin is coated first on the entire surface of the insulating base layer 3 including the conductive pattern 4 and the tin layer 32, and dried by heating at, e.g., 70 to 120° C. Then, the solution is exposed to light via a photomask, and then developed to form the cover coating 23 in a pattern which covers the tin layer 32 formed on the surface of each of the wires 12, and exposes the tin layer 32 formed on the surface of each of the terminal portions 11.

Next, as shown in FIG. 5(f), the uncured cover coating 23 is cured by heating, while the tin layer 32 is heated and cooled to form the tin-based thin layer 5.

To cure the cover coating 23, and form the tin-based thin layer 5, the suspension board with circuit 1 in the process of production which is formed with the tin layer 32 and the cover coating 23 is heated in vacuum to a temperature of not less than 350° C. (heating step).

In the heating step, e.g., the suspension board with circuit 1 is loaded in a reduced-pressure drier or the like, and heated with a heater, while the reduced-pressure drier is evacuated with a vacuum pump (decompression pump).

Specifically, a vacuum pressure in the heating step is in a range of, e.g., not more than 3 Pa, or preferably not more than 1 Pa, and normally not less than 0.1 Pa. As an atmosphere in vacuum (under a reduced pressure), an oxygen-containing atmosphere such as an aerial atmosphere or an inert gas atmosphere such as a nitrogen atmosphere, e.g., is used, or preferably an inert gas atmosphere is used.

A heating temperature is a temperature which allows the cover coating 23 to be cured, and which does not decompose the insulating base layer 3 and the cover coating 23. The heating temperature is preferably in a range of, e.g., not less than 360° C., or more preferably not less than 380° C., and normally not more than 450° C., or preferably not more than 410° C. A heating period is in a range of, e.g., 60 to 300 minutes, or preferably 80 to 240 minutes. A rate of heating from an ordinary temperature to the heating temperature is in a range of, e.g., 1 to 6° C. per minute, or preferably 4 to 6° C. per minute.

By the heating step, the uncured cover coating 23 is cured to form the insulating cover layer 6, while tin is simultaneously diffused into the conductive material of the conductive pattern 4 and the conductive material of the conductive pattern 4 is diffused into tin to form the tin alloy layer 33 (see FIG. 3).

In the diffusion of tin, tin in the tin layer 32 formed on the surface of the conductive pattern 4 is inwardly diffused to form the tin alloy layer 33 having a thickness larger than that of the tin layer 32 before heating.

By the diffusion of tin, the tin layer 32 is replaced with the tin alloy layer 33 so that the tin layer 32 substantially disappears.

Next, after the heating step, the suspension board with circuit 1 in the process of production which includes the tin alloy layer 33 is cooled in vacuum to a temperature (ultimate cooling temperature) between the heating temperature and an ordinary temperature (first cooling step).

In the first cooling step, e.g., the reduced-pressure drier and the like used in the heating step described above are used continuously. Specifically, the operation of the heater of the reduced-pressure drier is stopped, while the operation of the vacuum pump is continued.

The ultimate cooling temperature in the first cooling step is any temperature selected within a range of, e.g., not less than 100° C. and less than 350° C., preferably 150 to 300° C., or more preferably 200 to 250° C. The cooling rate (in the case of cooling from the heating temperature to the ultimate cooling temperature) is in a range of, e.g., 0.1 to 5° C. per minute, or preferably 0.5 to 4° C. per minute. The vacuum pressure in the first cooling step is the same as the vacuum pressure in the heating step described above.

Then, after the first cooling step, the suspension board with circuit 1 in the process of production which includes the tin alloy layer 33 is cooled under an atmospheric pressure (a second cooling step as a cooling step).

In the second cooling step, the reduced-pressure drier and the like used in the first cooling step are used continuously. Specifically, the operation of the vacuum pump is stopped in a state where the operation of the heater has been stopped, and the inside of the reduced-pressure drier is opened to an aerial atmosphere.

In the second cooling step, the suspension board with circuit 1 is cooled, e.g., from the cooling temperature in the first cooling step to an ordinary temperature (a room temperature which is specifically in the range of 10 to 40° C., or more specifically about 25° C.). A cooling rate (the rate of cooling from the ultimate cooling temperature to an ordinary temperature) is in a range of, e.g., 1 to 5° C. per minute, or preferably 2 to 4° C. per minute.

By the second cooling step, the surface (substantially, only tin atoms) of the tin alloy layer 33 is oxidized to form the tin oxide layer 31. That is, an extremely small amount of oxygen that has entered into the space between the outer surface of the tin alloy layer 33 and the inner surface of the cover coating 23 serves as an oxygen source for oxidizing the tin alloy layer 33 (tin atoms) to oxidize the surface of the tin alloy layer 33.

Through the oxidization of the surface of the tin alloy layer 33, the tin alloy layer 33 is formed thinner than before the second cooling step.

In this manner, the tin-based thin layer 5 made of the tin alloy layer 33 and the tin oxide layer 31 is formed (see FIG. 3).

Next, as shown in FIG. 5(g), the metal opening 8 is formed in the metal supporting board 2.

For the formation of the metal opening 8, e.g., a known etching method such as dry etching (e.g., plasma etching) or wet etching (e.g., chemical etching), drilling, or laser processing is used. Preferably, chemical etching is used.

Next, as shown in FIG. 5(h), the base opening 9 is formed in the insulating base layer 3.

For the formation of the base opening 9, e.g., a known etching method such as dry etching (e.g., plasma etching) or wet etching (e.g., chemical etching), drilling, or laser processing is used. Preferably, plasma etching is used.

Next, as shown in FIG. 5(i), the gold plating layer 7 is formed continuously on the lower surfaces of the terminal portions 11 and on the surface of the tin-based thin layer 5 which is formed on the upper surfaces and both side surfaces of the terminal portions 11.

The gold plating layer 7 is formed by, e.g., electrolytic plating or electroless plating, or preferably by electrolytic plating.

In the suspension board with circuit 1 and the producing method thereof, the tin-based thin layer 5 is formed on the surface of the conductive pattern 4 including the terminal portions 11. Therefore, the strength of the terminal portions 11 can be sufficiently improved. As a result, it is possible to obtain the suspension board with circuit 1 having excellent connection reliability.

In addition, since the tin-based thin layer 5 including the tin oxide layer 31 is interposed between the conductive pattern 4 and the insulating cover layer 6, it is possible to prevent the degradation of the adhesion between the conductive pattern 4 and the insulating cover layer 6 despite the coverage of the conductive pattern 4 with the tin alloy layer 33.

As a result, even after the long-term use of the suspension board with circuit 1, it is possible to prevent the insulating cover layer 6 from peeling (floating up) from the conductive pattern 4, and prevent the occurrence of discoloration of the wires 12.

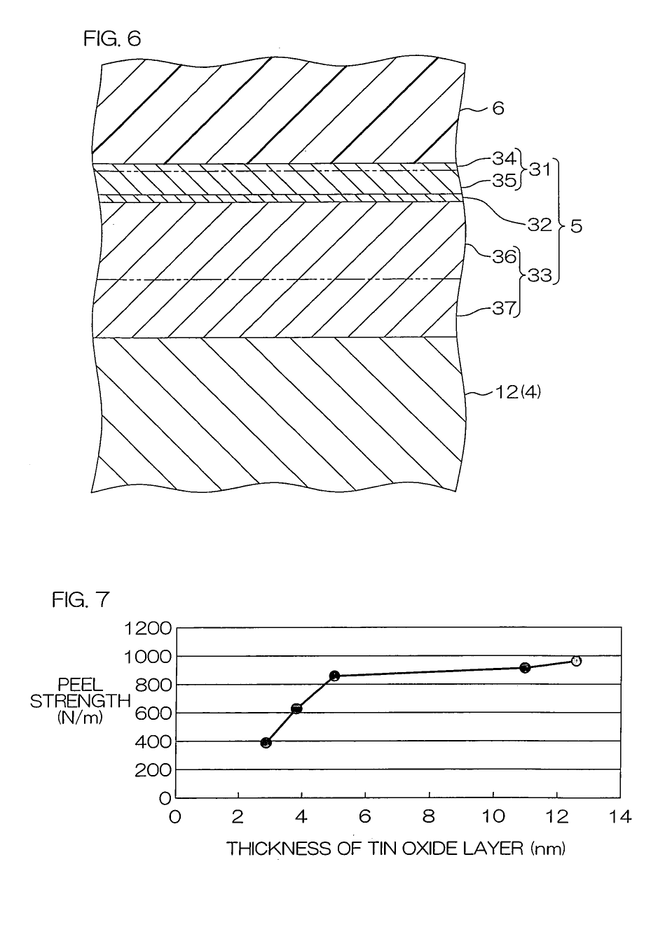

In the description given above, the tin-based thin layer 5 is formed of the tin alloy layer 33 and the tin oxide layer 31 by way of example. However, the structure of the tin-based thin layer 5 is not limited thereto. It is sufficient as long as at least the tin alloy layer 33 is formed. For example, the tin layer 32 may also remain after the heating step. For example, as shown in FIG. 6, the tin-based thin layer 5 can also be formed of the tin alloy layer 33, the tin layer 32, and the tin oxide layer 31.

In FIG. 6, the tin layer 32 is substantially made only of tin (Sn), and interposed between the tin alloy layer 33 and the tin oxide layer 31, specifically between the second tin alloy layer 36 and the first tin oxide layer 35.

The thickness of the tin layer 32 is in a range of, e.g. 1 to 1500 nm, or preferably 1 to 500 nm.

In the description given above, the first cooling step is performed. However, it is also possible to, e.g., perform the second cooling step under an atmospheric pressure immediately after the heating step without performing the first cooling step. In that case, the cooling rate (the rate of cooling from the heating temperature to an ordinary temperature) in the second cooling step is in a range of, e.g., 1 to 5° C. per minute, or preferably 2 to 4° C. per minute.

In the description given above, the first cooling step in vacuum and the second cooling step under an atmospheric pressure are sequentially performed. However, it is also possible to sequentially perform a third cooling step as a cooling step in vacuum, and a re-heating step under an atmospheric pressure, instead of performing the first cooling step and the second cooling step.

That is, after the heating step described above, the third cooling step is performed instead of the first cooling step and the second cooling step to cool the suspension board with circuit 1 in the process of production which includes the tin alloy layer 33 in vacuum.

That is, in the third cooling step, the reduced-pressure drier and the like used in the heating step described above are used continuously. Specifically, the suspension board with circuit 1 is cooled to an ordinary temperature (a room temperature which is specifically in the range of 10 to 40° C., or more specifically about 25° C.) by stopping the operation of the heater, while continuing the operation of the vacuum pump.

A cooling rate (in the case of cooling from the heating temperature to an ordinary temperature) in the third cooling step is in a range of, e.g., 1 to 10° C. per minute, or preferably 2 to 3° C. per minute. A vacuum pressure in the third cooling step is in a range of, e.g., not more than 3 Pa, or preferably not more than 1 Pa, and normally not less than 0.1 Pa. As an atmosphere in vacuum, an oxygen-containing atmosphere such as an aerial atmosphere or an inert gas atmosphere such as a nitrogen atmosphere, e.g., is used, or preferably an inert gas atmosphere is used.

In the re-heating step, the suspension board with circuit 1 after the third cooling step is heated under an atmospheric pressure to a temperature of not less than 150° C.

In the re-heating step, it is possible to use, e.g., the reduced-pressure drier mentioned above (without using a vacuum pump), or a drier different from the reduced-pressure drier.

A heating temperature is preferably in a range of, e.g., 150 to 200° C., or more preferably 160 to 200° C. A heating period is in a range of, e.g., 10 to 120 minutes, or preferably 20 to 60 minutes. A rate of heating from an ordinary temperature to the heating temperature is in a range of, e.g., 1 to 20° C. per minute, or preferably 5 to 10° C. per minute.

After the re-heating step, the suspension board with circuit 1 is cooled (slowly cooled), e.g., under an atmospheric pressure or in vacuum. Preferably, the suspension board with circuit 1 is cooled (slowly cooled) under an atmospheric pressure to an ordinary temperature.

To cool the suspension board with circuit 1 under an atmospheric pressure, the heater of the drier is stopped, or the suspension board with circuit 1 is retrieved from the drier, and allowed to stand under an atmospheric pressure. A rate of cooling (slow cooling) is in a range of, e.g., 1 to 50° C. per minute.

By the third cooling step and the re-heating step, the surface of the tin alloy layer 33 is oxidized to form the tin oxide layer 31. As a result, the tin-based thin layer 5 made of the tin alloy layer 33 and the tin oxide layer 31 is formed.

In the description given above, the terminal portions 11 of the suspension board with circuit 1 are formed as flying leads. However, it is also possible to form the terminal portions 11 such that, e.g., the lower surfaces (back surfaces) thereof are supported from below by the insulating base layer 3 and the metal supporting board 2 without forming the base opening 9 and the metal opening 8 at the positions corresponding to the terminal portions 11.

In the description given above, the wired circuit board of the present invention is described by way of example as the suspension board with circuit 1 including the metal supporting board 2. However, the wired circuit board of the present invention is not limited thereto, and is widely applicable to other wired circuit boards such as, e.g., a flexible wired circuit board which includes the metal supporting board 2 as a reinforcing layer, and a flexible wired circuit board which does not include the metal supporting board 2.

### EXAMPLES

Hereinbelow, the present invention is described more specifically by showing the examples and the comparative examples. However, the present invention is by no means limited to the examples and the comparative examples.

### Example 1

A metal supporting board made of a stainless steel (SUS304) foil with a thickness of 20 μm was prepared (see FIG. 4(a)).

Then, a solution of a photosensitive polyamic acid resin was uniformly coated on the entire surface of the metal supporting board, and dried by heating at 90° C. to form a base coating. Subsequently, the base coating was exposed to light via a photomask, developed, and then cured (imidized) by heating at 370° C. to form an insulating base layer made of polyimide with a thickness of 10 μm on the metal supporting board (see FIG. 4(b)).

Then, a chromium thin film with a thickness of 50 nm and a copper thin film with a thickness of 100 nm were successively formed on the entire surface of the insulating base layer by a sputter deposition method to form a seed film. Subsequently, on the upper surface of the seed film, a plating resist in a pattern reverse to a conductive pattern was formed, and then the conductive pattern made of copper with a thickness of 10 μm was formed by electrolytic copper plating (see FIG. 4(c)). The width of each of wires and the width of each of terminal portions were 100 μm. The spacing between the individual wires and the spacing between the individual terminal portions were 20 μm.

Then, a tin layer with a thickness of 485 nm was formed on the surface of the conductive pattern by electroless tin plating (see FIG. 4(d)).

Then, a solution of a photosensitive polyamic acid resin was coated on the entire surface of the insulating base layer including the tin layer, and dried by heating at 90° C. Subsequently, the solution was exposed to light via a photomask, and then developed to form a cover coating in a pattern in which a cover opening was formed, and the tin layer was exposed (see FIG. 4(e)).

Then, a suspension board with circuit in the process of production which was formed with the tin layer and the cover coating was loaded in a reduced-pressure drier, and a heater and a vacuum pump were operated to heat the suspension board with circuit in vacuum (1 Pa) from 25° C. to 400° C. at a heating rate of 6° C. per minute. Subsequently, the heating was continued in vacuum (1 Pa) at 400° C. for 120 minutes (heating step).

By the heating, the cover coating was cured (imidized), and a tin alloy layer made of a tin-copper alloy in which tin was diffused in copper was formed (see FIG. 5(f)).

Subsequently, the operation of the heater of the reduced-pressure drier was stopped so that the suspension board with circuit was cooled in vacuum (1 Pa) to 250° C. (first cooling step). A cooling rate in the first cooling step was 0.6° C. per minute.

Then, the operation of the vacuum pump was stopped, and the inside of the reduced-pressure drier was opened to an aerial atmosphere so that the suspension board with circuit was cooled under an atmospheric pressure from 250° C. to 25° C. (second cooling step). The cooling rate in the second cooling step was 3° C. per minute.

Then, a metal opening was formed by etching the metal supporting board by chemical etching (see FIG. 5(g)). Subsequently, a base opening was formed by etching the insulating base layer by plasma etching (see FIG. 5(h)).

Thereafter, a gold plating layer with a thickness of 2 μm was formed continuously on the lower surfaces of the terminal portions and on the surface of the tin alloy layer which was formed on the upper surfaces and both side surfaces of the terminal portions (see FIG. 5(i)).

### Examples 2 to 5

Suspension boards with circuit were obtained in the same manner as in EXAMPLE 1 except that the thickness of the tin layer (the thickness of the tin layer before the heating step) was changed to the values in the parentheses in Table 1.

### Examples 6 to 10

Suspension boards with circuit were obtained by forming tin-based thin layers in the same manner as in EXAMPLE 1 except that a third cooling step in vacuum and a re-heating step under an atmospheric pressure were performed instead of performing the first cooling step in vacuum and the second cooling step under an atmospheric pressure.

That is, in the third cooling step after the heating step, the suspension boards with circuit in the process of production which included tin alloy layers were cooled in vacuum (1 Pa) from 400° C. to 25° C. by stopping the operation of the heater, while continuing the operation of the vacuum pump of the reduced-pressure drier used in the heating step. A cooling rate in the third cooling step was 3° C. per minute.

In the re-heating step after the third cooling step, the suspension boards with circuit were each loaded in another drier, and heated under an atmospheric pressure for 30 minutes to 200° C. at a heating rate of 10° C. per minute. Thereafter, the suspension boards with circuit were each slowly cooled under an atmospheric pressure. A slow cooling rate was 5° C. per minute.

### Comparative Example 1

A suspension board with circuit was obtained in the same manner as in EXAMPLE 1 except that, in the heating step, the heating temperature was changed to 150° C., and the heating period was changed to 60 minutes and, after the heating step, the suspension board with circuit was slowly cooled under an atmospheric pressure from 150° C. to 25° C. instead of performing the first cooling step and the second cooling step.

### Comparative Example 2

A suspension board with circuit was obtained in the same manner as in EXAMPLE 1 except that, in the heating step, the pressure was changed from a vacuum pressure to an atmospheric pressure and, after the heating step, the suspension board with circuit was slowly cooled in vacuum (1 Pa) from 400° C. to 25° C. using a reduced-pressure drier and operating the vacuum pump, while stopping the operation of the heater, instead of performing the first cooling step and the second cooling step.

### (Evaluation)

(1) In each of the suspension boards with circuit of EXAMPLES and COMPARATIVE EXAMPLES, the respective compositions and thicknesses of the individual layers in the tin-based thin layers were measured based on a SERA method (IPC-4554).

As a result, in each of the tin-based thin layers of EXAMPLES 1 to 10, it was recognized that only a first tin alloy layer made of Cu₃Sn, a second tin alloy layer made of Cu₆Sn₅, a first tin oxide layer made of SnO₂, and a second tin oxide layer made of SnO were present. It was also recognized that the tin layer made of Sn had disappeared.

By contrast, in each of the tin-based thin layers of COMPARATIVE EXAMPLES 1 and 2, it was recognized that the first tin alloy layer made of Cu₃Sn, and the second tin alloy layer made of Cu₆Sn₅ were present. It was also recognized that the tin layer made of Sn had disappeared.

The thicknesses of the tin-based thin layers are shown in Table 1.

(2) Connection Strength of Terminal Portions

The external connection terminals of the suspension board with circuit of each of EXAMPLES and COMPARATIVE EXAMPLES were connected to terminal portions made of gold pads of a read/write board by applying ultrasonic vibration using a bonding tool. Thereafter, a peel test which involved peeling in a 180-degree direction was performed using a universal tester (Tensilon™ commercially available from A&D Co., Ltd.), and the connection strength of the terminal portions was evaluated. The result of the evaluation is shown in Table 1.

(3) Peel Strength of Insulating Cover Layer

In the suspension board with circuit of each of EXAMPLES and COMPARATIVE EXAMPLES, a peel test was performed using a universal tester (Tensilon™ commercially available from A&D Co., Ltd.). In the peel test, the insulating cover layer was peeled from the insulating base layer and the metal supporting board at the front end portion by holding the front end portion of the insulating cover layer with one chuck, holding the respective front end portions of the insulating base layer and the metal supporting board with the other chuck, and pulling them apart in a 180-degree direction. The adhesion between the wires and the insulating cover layer at that time was measured as the peel strength of the insulating cover layer. The result of the evaluation is shown in Table 1.

TABLE 1

| | | | Examples/Comparative Examples | | | | | | | | | | | |
|---|---|---|---|---|---|---|---|---|---|---|---|---|---|---|
| | | | | | | | | | | | | | Compar- | Compar- |
| | | | Exam- | Exam- | Exam- | Exam- | Exam- | Exam- | Exam- | Exam- | Exam- | Exam- | arive | arive |
| | | | ple 1 | ple 2 | ple 3 | ple 4 | ple 5 | ple 6 | ple 7 | ple 8 | ple 9 | ple 10 | Example 1 | Example 2 |
| Thickness | Tin-Based | | 763 | 1053.9 | 1065.4 | 1001.2 | 1093 | 763 | 1053.9 | 1065.4 | 1001.2 | 1093 | 980 | 830 |
| of Each | Thin Layer | | | | | | | | | | | | | |
| Layer | Tin | First | 0.3 | 0.4 | 0.4 | 0.2 | 0.4 | 0.3 | 0.4 | 0.4 | 0.2 | 0.4 | — | — |
| (nm) | Oxide | Second | 2.7 | 3.5 | 5 | 11 | 12.6 | 2.7 | 3.5 | 5 | 11 | 12.6 | — | — |
| | Layer | Total | 3 | 3.9 | 5.4 | 11.2 | 13 | 3 | 3.9 | 5.4 | 11.2 | 13 | — | — |
| | | Thick- | | | | | | | | | | | | |
| | | ness | | | | | | | | | | | | |
| | Tin Layer *1 | | −485 | −500 | −510 | −475 | −520 | −480 | −500 | −510 | −475 | −520 | −500 | −500 |
| | Tin | First | 450 | 620 | 710 | 520 | 650 | 450 | 620 | 710 | 520 | 650 | 730 | 480 |
| | Alloy | Second | 310 | 430 | 350 | 470 | 430 | 310 | 430 | 350 | 470 | 430 | 250 | 350 |
| | Layer | Total | 760 | 1050 | 1060 | 990 | 1080 | 760 | 1050 | 1060 | 990 | 1080 | 980 | 830 |
| | | Thick- | | | | | | | | | | | | |
| | | ness | | | | | | | | | | | | |

| | | | | | | | | | | | | | |
|---|---|---|---|---|---|---|---|---|---|---|---|---|---|
| Evaluation | Peel Strength | 392 | 627 | 862 | 911 | 960 | 392 | 627 | 862 | 911 | 960 | 10 | 0 |
| | (N/m) | | | | | | | | | | | | |

*1: Thickness of Tin Layer Before Heating Step

While the illustrative embodiments of the present invention are provided in the above description, such is for illustrative purpose only and it is not to be construed limitative. Modification and variation of the present invention which will be obvious to those skilled in the art is to be covered by the following claims.

What is claimed is:

1. A wired circuit board comprising:
an insulating base layer;
a conductive pattern formed on the insulating base layer;
a tin-based thin layer formed on a surface of the conductive pattern, and containing at least tin oxide; and
an insulating cover layer formed on the insulating base layer so as to cover the tin-based thin layer.

2. The wired circuit board according to claim 1, wherein
the tin-based thin layer includes a tin oxide layer made of the tin oxide, and
a thickness of the tin oxide layer is in a range of 5 to 50 nm.

3. A wired circuit board obtained by a producing method of a wired circuit board, the producing method comprising:
forming an insulating base layer;
forming a conductive pattern on the insulating base layer;
forming a tin layer on a surface of the conductive pattern;
heating the tin layer in vacuum to a temperature of not less than 350° C.;
cooling, after the heating, the tin layer under an atmospheric pressure to form a tin-based thin layer containing at least tin oxide; and
forming an insulating cover layer on the insulating base layer so as to cover the tin-based thin layer.

4. A wired circuit board obtained by a producing method of a wired circuit board, the producing method comprising:
forming an insulating base layer;
forming a conductive pattern on the insulating base layer;
forming a tin layer on a surface of the conductive pattern;
heating the tin layer in vacuum to a temperature of not less than 350° C.;
cooling, after the heating, the tin layer in vacuum;
heating, after the cooling, the tin layer to a temperature of not less than 150° C. under an atmospheric pressure to form a tin-based thin layer containing at least tin oxide; and
forming an insulating cover layer on the insulating base layer so as to cover the tin-based thin layer.

5. The wired circuit board according to claim 3, wherein
the step of forming the insulating cover layer includes:
laminating an uncured resin; and
curing the laminated uncured resin by heating, and
the curing and the heating are simultaneously performed.

6. The wired circuit board according to claim 4, wherein
the step of forming the insulating cover layer includes:
laminating an uncured resin; and
curing the laminated uncured resin by heating, and
the curing and the heating are simultaneously performed.

7. A producing method of a wired circuit board, the producing method comprising:
forming an insulating base layer;
forming a conductive pattern on the insulating base layer;
forming a tin layer on a surface of the conductive pattern;
heating the tin layer in vacuum to a temperature of not less than 350° C.;
cooling, after the heating, the tin layer under an atmospheric pressure to form a tin-based thin layer containing at least tin oxide; and
forming an insulating cover layer on the insulating base layer so as to cover the tin-based thin layer.

8. A producing method of a wired circuit board, the producing method comprising:
forming an insulating base layer;
forming a conductive pattern on the insulating base layer;
forming a tin layer on a surface of the conductive pattern;
heating the tin layer in vacuum to a temperature of not less than 350° C.;
cooling, after the heating, the tin layer in vacuum;
heating, after the cooling, the tin layer to a temperature of not less than 150° C. under an atmospheric pressure to form a tin-based thin layer containing at least tin oxide; and
forming an insulating cover layer on the insulating base layer so as to cover the tin-based thin layer.

9. The producing method of a wired circuit board according to claim 7, wherein
the step of forming the insulating cover layer includes:
laminating an uncured resin; and
curing the laminated uncured resin by heating, and
the curing and the heating are simultaneously performed.

10. The producing method of a wired circuit board according to claim 8, wherein
the step of forming the insulating cover layer includes:
laminating an uncured resin; and
curing the laminated uncured resin by heating, and
the curing and the heating are simultaneously performed.
